(19) United States
(12) Patent Application Publication
(10) Pub. No.: US 2026/0157212 A1
(43) Pub. Date: Jun. 4, 2026

(54) ELECTRONIC COMPONENT MOUNTING APPARATUS AND ELECTRONIC COMPONENT MOUNTING METHOD

(71) Applicant: Murata Manufacturing Co., Ltd., Kyoto-fu (JP)

(72) Inventors: Takuya KUDO, Nagaokakyo-shi (JP); Yoshiaki SATAKE, Nagaokakyo-shi (JP); Wataru DOI, Nagaokakyo-shi (JP); Tatsuya FUNAKI, Nagaokakyo-shi (JP); Kei ARAI, Nagaokakyo-shi (JP)

(73) Assignee: Murata Manufacturing Co., Ltd., Kyoto-fu (JP)

(21) Appl. No.: 19/459,462

(22) Filed: Jan. 26, 2026

Related U.S. Application Data
(63) Continuation of application No. PCT/JP2024/031056, filed on Aug. 29, 2024.

(30) Foreign Application Priority Data
Sep. 12, 2023 (JP) 2023-147543

(51) Int. Cl. H10W 72/00

(52) U.S. Cl. CPC H10W 72/07183

(57) ABSTRACT

A mounting apparatus of an electronic component includes a stage, a mounting head, an infrared camera, and a first infrared source. The stage has a main surface on which the substrate can be placed. The mounting head is for mounting the electronic component on the substrate. The infrared camera can detect infrared rays. The first infrared source can emit at least infrared rays. The mounting head is movable within a two-dimensional range parallel to the main surface. The infrared camera can photograph the inside of a mounting region of the electronic component.

### CROSS-REFERENCE TO RELATED APPLICATIONS

This application claims benefit of priority to International Patent Application No. PCT/JP2024/031056, filed Aug. 29, 2024, and to Japanese Patent Application No. 2023-147543, filed Sep. 12, 2023, the entire contents of each are incorporated herein by reference.

### BACKGROUND

### Technical Field

The present disclosure relates to an electronic component mounting apparatus and an electronic component mounting method.

### Background Art

The component mounting system described in Japanese Patent Application Laid-Open No. 2018-182070 includes a solder printing apparatus, an adhesive applying apparatus, an inspection apparatus, and a component mounter. The substrate on which the electronic component is to be mounted is subjected to various types of processing while being transferred between the devices arranged along the transfer line. The solder printing apparatus prints a predetermined amount of solder on an electrode pattern of the substrate. The adhesive applying apparatus applies an adhesive to a predetermined portion of the substrate. The inspection apparatus inspects the printed state of the solder on the substrate and the applied state of the adhesive on the substrate. The component mounter mounts an electronic component on a substrate determined to be a non-defective product by the inspection apparatus.

### SUMMARY

In the component mounting system as described in Japanese Patent Application Laid-Open No. 2018-182070, the component mounter and the inspection apparatus are separate devices. Therefore, in order to complete both the mounting of the electronic component on the substrate and the inspection, it is essential to transfer the substrate between the apparatuses. Therefore, time, labor, and the like for transferring the substrate occur.

Accordingly, the present disclosure provides an electronic component mounting apparatus including a stage having a main surface on which a substrate can be placed, a mounting head for mounting an electronic component on the substrate, an infrared camera capable of detecting infrared rays, and a first infrared source capable of emitting at least infrared rays. The mounting head is movable within a two-dimensional range parallel to the main surface, and the infrared camera is capable of photographing an inside of a mounting region of the electronic component.

Further, the present disclosure provides an electronic component mounting method performed by a mounting apparatus, in which the mounting apparatus includes a stage having a main surface on which a substrate can be placed, a mounting head for mounting an electronic component on the substrate, an infrared camera capable of detecting infrared rays, and an infrared source capable of emitting at least infrared rays. The mounting head is movable within a two-dimensional range parallel to the main surface, and the infrared camera is capable of photographing an inside of a mounting region of the electronic component. The method comprises a substrate placing step of placing the substrate on the main surface of the stage, a mounting step of mounting the electronic component on the substrate via an adhesive layer while relatively moving the mounting head with respect to the substrate on the stage, and an inspection step of inspecting the substrate, the electronic component, and the adhesive layer by photographing the substrate, the electronic component, and the adhesive layer with the infrared camera while emitting infrared rays from the infrared source after start of the mounting step.

According to the above configuration, time, labor, and the like for transferring the substrate can be omitted.

### BRIEF EXPLANATION OF THE DRAWINGS

FIG. 1 is a schematic configuration diagram of a mounting apparatus;

FIG. 2 is a sectional view of an electronic component;

FIG. 3 is a flowchart illustrating an electronic component mounting method;

FIG. 4 is a diagram for explaining the electronic component mounting method;

FIG. 5 is a diagram for explaining the electronic component mounting method;

FIG. 6 is a diagram for explaining the electronic component mounting method;

FIG. 7 is a diagram for explaining the electronic component mounting method;

FIG. 8 is a diagram for explaining an aspect of incidence of infrared rays on an electronic component;

FIG. 9 is a schematic configuration diagram of a mounting apparatus according to a modification; and

FIG. 10 is a schematic configuration diagram of a mounting apparatus according to a modification.

### DETAILED DESCRIPTION

Hereinafter, an embodiment of an electronic component mounting apparatus will be described with reference to the drawings. It is to be noted that constituent elements may be shown in an enlarged manner in the drawings for the sake of easy understanding. In some cases, the dimension ratio of a component differs from an actual dimension ratio or a dimension ratio in another drawing.

### Overall Configuration

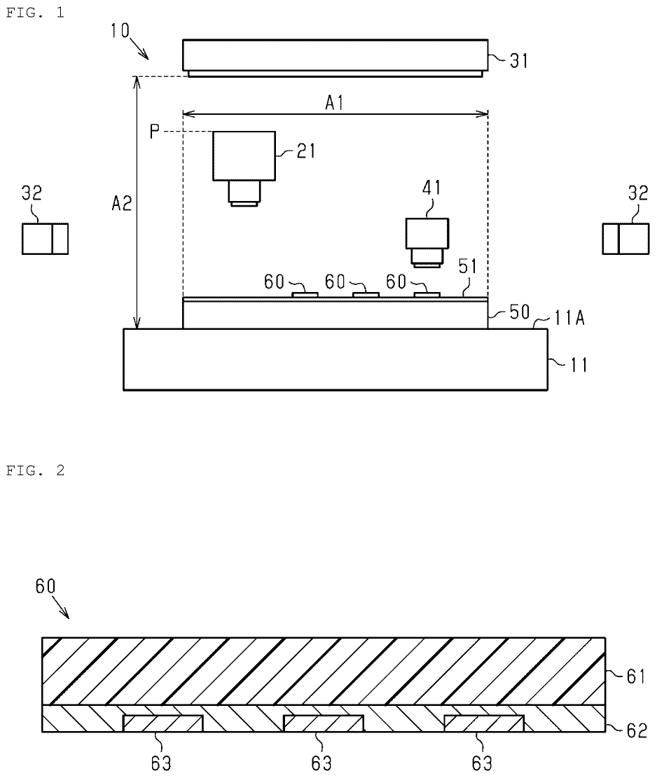

As illustrated in FIG. 1, a mounting apparatus 10 includes a stage 11 and a mounting head 21.

The stage 11 is a substantially square plate. The stage 11 has a main surface 11A on which a substrate 50 can be placed. The main surface 11A of the stage 11 has a substantially square shape. Note that the main surface 11A here is a surface having the largest area of the stage 11, and is a surface facing upward when the mounting apparatus 10 is placed on a floor surface or the like. The material of the stage 11 is, for example, metal. Although not illustrated, the substrate 50 placed on the stage 11 can be fixed so as to be relatively immovable with respect to the stage 11 using a clamp mechanism or the like.

The mounting head 21 is for mounting an electronic component 60 on the substrate 50. In this embodiment, the electronic component 60 is referred to as a so-called semiconductor electronic component. Specifically, the mounting head 21 includes a suction mechanism (not illustrated). By driving the suction mechanism, the mounting head 21 holds the electronic component 60 by negative pressure. The mounting head 21 releases the electronic component 60 by stopping the suction mechanism.

The mounting head 21 is supported by an arm and a frame (not illustrated). The mounting head 21 is movable within a two-dimensional range parallel to the main surface 11A by power from a power source such as an electric motor. The mounting head 21 is movable in a region including a first range A1 in a direction parallel to the main surface 11A. In the present embodiment, the first range A1 corresponds to a region where the substrate 50 exists in a state where the substrate 50 is placed on the stage 11. For example, the first range A1 can be a range of φ300 mm corresponding to the substrate 50 of φ300 mm. Further, the mounting head 21 is also movable in a direction orthogonal to the main surface 11A. Note that the moving mechanism of the mounting head 21 is known as disclosed in, for example, Japanese Patent Application Laid-Open No. 2001-127500, and thus a detailed description thereof will be omitted.

The mounting apparatus 10 includes a first infrared source 31, a second infrared source 32, and an infrared camera 41.

The first infrared source 31 can emit infrared rays. The wavelength of the infrared ray is a wavelength that can be detected by the infrared camera 41. For example, the first infrared source 31 is an infrared light emitting diode (LED), a halogen light source, or the like. The first infrared source 31 is located within a movable range of the mounting head 21 in a direction parallel to the main surface 11A. More specifically, the first infrared source 31 is located in a region where the electronic component 60 can be mounted on the substrate 50, that is, in a mounting region of the electronic component 60, in a direction parallel to the main surface 11A. In this embodiment, the electronic component 60 can be mounted on the entire main surface of the substrate 50. Therefore, the first infrared source 31 is located within the first range A1. In the present embodiment, the first infrared source 31 has a circular shape of φ300 mm. The first infrared source 31 is located immediately above the substrate 50 in a state where the substrate 50 is fixed to the stage 11. The first infrared source 31 irradiates the substrate 50 with infrared rays from immediately above to below. The infrared rays emitted from the first infrared source 31 have diffusibility. In other words, the infrared rays emitted from the first infrared source 31 do not have strong directivity like so-called laser light.

Here, as described above, the mounting head 21 is movable in a direction orthogonal to the main surface 11A. The position of the upper end of the mounting head 21 when the mounting head 21 is farthest from the stage 11 in a direction orthogonal to the main surface 11A is defined as an uppermost position P. The first infrared source 31 is located on the side far from the main surface 11A with respect to the uppermost position P, that is, on the upper side in a direction orthogonal to the main surface 11A.

The second infrared source 32 can emit infrared rays having the same wavelength as those of the first infrared source 31. The wavelength of the infrared ray is a wavelength that can be detected by the infrared camera 41. For example, the second infrared source 32 is an infrared LED. The second infrared source 32 has a ring shape. Specifically, the second infrared source 32 extends so as to surround the stage 11 from the outside. The ring-shaped virtual central axis of the second infrared source 32 passes substantially through the center of the main surface 11A of the stage 11. In FIG. 1, only left and right parts of the second infrared source 32 are illustrated in an end surface view. The second infrared source 32 is located outside the mounting region of the electronic component 60 in a direction parallel to the main surface 11A. That is, the second infrared source 32 is located outside the first range A1. Here, in a direction orthogonal to the main surface 11A, a range from the position of the first infrared source 31 closest to the main surface 11A to the main surface 11A is defined as a second range A2. The second infrared source 32 is located in the second range A2 in a direction orthogonal to the main surface 11A.

In the present embodiment, the second infrared source 32 emits infrared rays toward the ring-shaped center of the second infrared source 32. In addition, the infrared rays emitted from the second infrared source 32 have diffusibility, similarly to the infrared rays emitted from the first infrared source 31. Therefore, the infrared rays emitted from the second infrared source 32 are obliquely incident on the main surface 11A. In other words, the second infrared source 32 irradiates the substrate 50 with infrared rays from positions oblique to the substrate 50 in a state where the substrate 50 is fixed to the stage 11.

The infrared camera 41 can detect and photograph infrared rays. That is, the infrared camera 41 can detect the infrared rays emitted from the first infrared source 31 and the second infrared source 32 and reflected by the electronic component 60 or the like. The infrared camera 41 can detect infrared rays having a wavelength of 1 μm or more and 15 μm or less (i.e., from 1 μm to 15 μm), for example.

The infrared camera 41 is supported by an arm and a frame (not illustrated). Then, the infrared camera 41 is movable within a two-dimensional range parallel to the main surface 11A by power from a power source such as an electric motor. Specifically, the infrared camera 41 is movable in the first range A1 which is a mounting region of the electronic component 60. In other words, the infrared camera 41 can photograph at least the inside of the mounting region of the electronic component 60. Furthermore, the infrared camera 41 is also movable in a direction orthogonal to the main surface 11A. The infrared camera 41 is movable independently of the mounting head 21. As a moving mechanism of the infrared camera 41, a moving mechanism similar to that of the mounting head 21 can be adopted.

### Substrate and Electronic Component

Hereinafter, the electronic component 60 mounted on the mounting apparatus 10 and the substrate 50 on which the electronic component 60 is mounted will be described.

As illustrated in FIG. 1, the substrate 50 has a plate shape. The substrate 50 has a circular shape of φ300 mm. The substrate 50 is conveyed onto the stage 11 by a carrier such as a conveyor. The surface of the substrate 50 is covered with an adhesive layer 51. Specifically, the adhesive layer 51 is located on the side opposite to the stage 11 when the substrate 50 is fixed to the stage 11. A material of the adhesive layer 51 is an organic substance such as a silicone resin, an epoxy resin, and a polyimide resin. The adhesive layer 51 has a thickness of 20 μm or less. The thickness of the adhesive layer 51 is, for example, 5 μm, more preferably 2.5 μm. The electronic component 60 is mounted on the substrate 50 via the adhesive layer 51.

As illustrated in FIG. 2, the electronic component 60 includes a base material 61, a barrier metal 62, and a wiring layer 63. The entire thickness of the electronic component 60 is, for example, 50 μm. The main component of the material of the base material 61 is metal silicon. That is, the material of the base material 61 is a material capable of transmitting infrared rays. The term “capable of transmitting” means that the maximum transmittance for infrared rays having a wavelength of 1 μm or more and 15 μm or less (i.e., from 1 μm to 15 μm) is 40% or more. In addition, the light transmittance depends on the band gap inherent to the substance. In other words, light that has a wavelength and energy equal to or less than the band gap inherent in the substance can pass through the substance. For example, the band gap of metal silicon is 1.1 eV. Therefore, when the wavelength is 1100 nm or more, the light remarkably passes through silicon.

The barrier metal 62 is located on the surface of the base material 61. The barrier metal 62 is interposed between the wiring layer 63 and the base material 61. The barrier metal 62 has a thin film shape.

The wiring layer 63 is located on the surface of the base material 61 with the barrier metal 62 interposed therebetween. The material of the wiring layer 63 is, for example, a conductive metal such as aluminum. That is, infrared rays are not transmitted through the wiring layer 63. When the electronic component 60 is mounted on the substrate 50, the electronic component is mounted such that the wiring layer 63 faces the substrate 50 side.

### Electronic Component Mounting Method

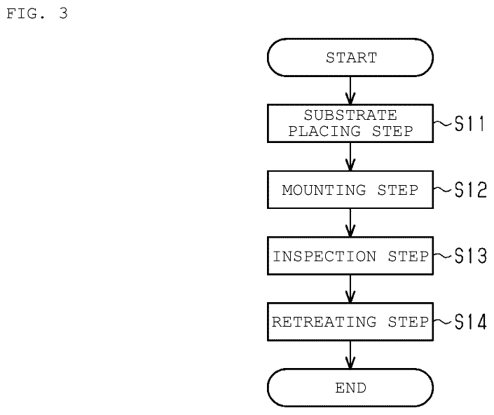

As illustrated in FIG. 3, the method for mounting electronic component 60 includes a substrate placing step S11, a mounting step S12, an inspection step S13, and a retreating step S14. The method for mounting the electronic component 60 is performed using the mounting apparatus 10.

In mounting the electronic component 60 on the substrate 50, first, the substrate placing step S11 is performed. As illustrated in FIG. 4, in the substrate placing step S11, the substrate 50 having the adhesive layer 51 formed on the surface thereof is placed on the main surface 11A of the stage 11 using a conveyor (not illustrated) or the like. At this time, the substrate 50 is placed such that the adhesive layer 51 is on the side opposite to the stage 11, that is, on the upper side. Then, the substrate 50 is fixed on the main surface 11A with a clamp or the like. In FIG. 4, the mounting head 21 and the infrared camera 41 are not illustrated.

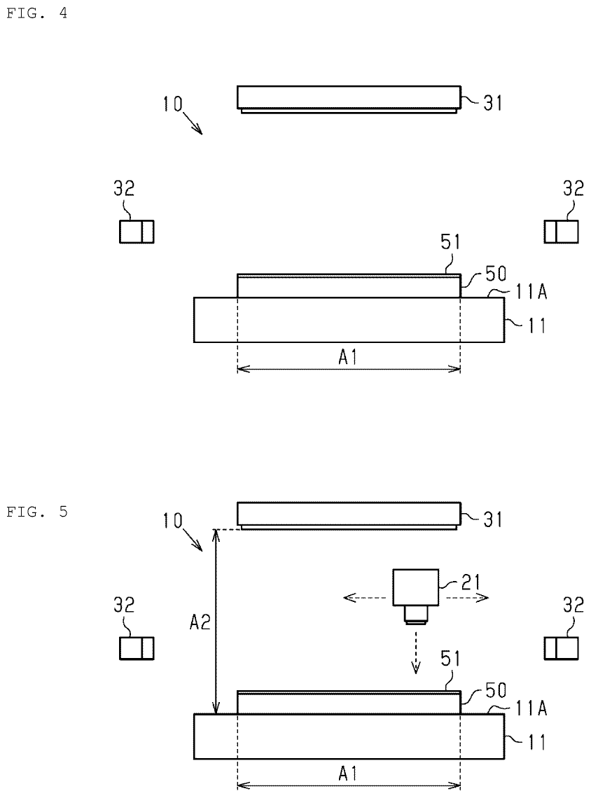

Then, as illustrated in FIG. 3, the mounting step S12 is performed. As illustrated in FIG. 5, in the mounting step S12, the electronic component 60 is mounted on the substrate 50 while the mounting head 21 is moved relative to the substrate 50 on the stage 11. Specifically, first, the electronic component 60 is held by the mounting head 21 by driving the suction mechanism outside the first range A1. Then, while holding the electronic component 60, the mounting head 21 is moved to a position within the first range A1 where the electronic component 60 is to be mounted. At this time, the mounting head 21 is located within the second range A2 in a direction orthogonal to the main surface 11A. Further, the mounting head 21 lowers the electronic component 60 toward the substrate 50. Then, the suction mechanism is stopped to release the electronic component 60 from the mounting head 21. As a result, the electronic component 60 is placed on the substrate 50. Note that the mounting head 21 is preferably moved from immediately above the electronic component 60 after releasing the electronic component 60. In the mounting step S12, a series of these steps is repeatedly executed to mount the plurality of electronic components 60 on the substrate 50. In FIG. 5, illustration of the infrared camera 41 is omitted.

Then, as illustrated in FIG. 3, the inspection step S13 is performed. As illustrated in FIG. 6, in the inspection step S13, while infrared rays are emitted from the first infrared source 31 and the second infrared source 32, an image of the electronic component 60 mounted on the substrate 50 and surroundings thereof is captured by the infrared camera 41. Then, by photographing the electronic component 60 with the infrared camera 41, the substrate 50, the electronic component 60, and the adhesive layer 51 between the substrate 50 and the electronic component 60 are inspected. Specifically, first, the infrared camera 41 is moved within the first range A1 and immediately above the electronic component 60 to be imaged. At this time, the infrared camera 41 is located within the second range A2 in a direction orthogonal to the main surface 11A. In this state, the electronic component 60 and the surroundings thereof are photographed using the infrared camera 41. After one electronic component 60 is photographed, the infrared camera 41 is moved immediately above the electronic component 60 mounted on the substrate 50 and not photographed. In this manner, in the inspection step S13, the inspection is performed by repeatedly executing the movement and photographing of the infrared camera 41. Using the image captured by the infrared camera 41, for example, it is possible to inspect the appearance of the electronic component 60 after mounting, the mounting position accuracy of the electronic component 60, the presence or absence of voids in the adhesive layer 51, the mixing of foreign matters, and the like.

The inspection step S13 is started after start of the mounting step S12 on the first electronic component 60. In FIG. 3, for convenience, the inspection step S13 is illustrated to be performed after the mounting step S12. However, in the present embodiment, the inspection step S13 is performed on the electronic component 60 mounted on the substrate 50 in parallel with the mounting step S12 performed by the mounting head 21 on the electronic component 60 not mounted on the substrate 50.

Next, as illustrated in FIG. 3, after the mounting step S12 for all the electronic components 60 to be mounted on the substrate 50 is completed, the retreating step S14 is performed. As illustrated in FIG. 7, in the retreating step S14, the mounting head 21 is moved to the outside of the first range A1. In the present embodiment, the retreating step S14 is performed in parallel with the inspection step S13 performed by the infrared camera 41 on the electronic component 60 mounted on the substrate 50. When the inspection step S13 for all the electronic components 60 is completed, the infrared camera 41 is also moved to the outside of the first range A1.

### Incidence of Infrared Ray on Electronic Component

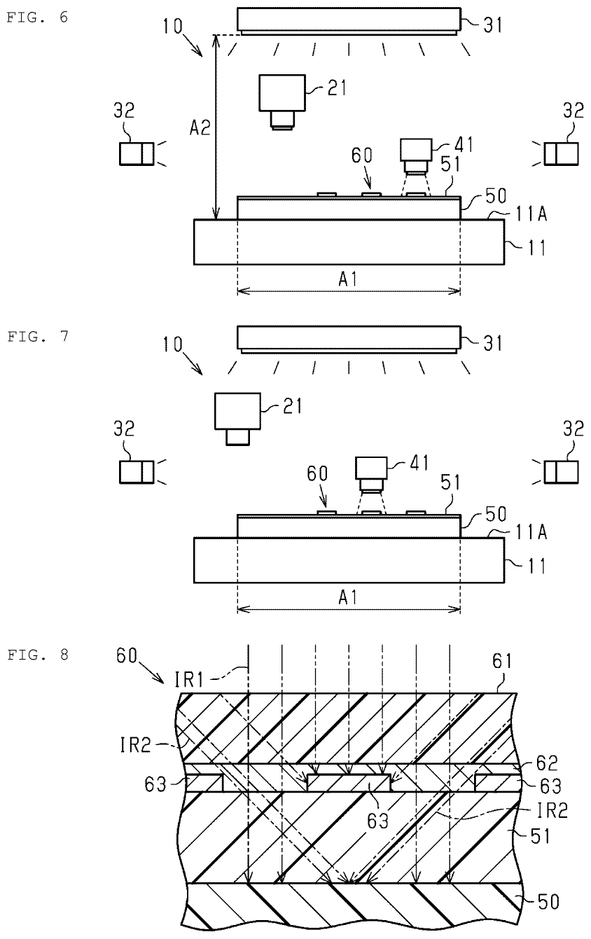

As illustrated in FIG. 8, an infrared ray IR1 emitted from the first infrared source 31 mainly travels straight in a direction orthogonal to the main surface 11A. However, the infrared ray IR1 does not pass through the wiring layer 63. Therefore, the infrared ray IR1 does not reach immediately below the wiring layer 63.

On the other hand, as described above, an infrared ray IR2 emitted from the second infrared source 32 diffuses and obliquely enters the main surface 11A. That is, the infrared ray IR2 emitted from the second infrared source 32 is also obliquely incident on the electronic component 60. Therefore, a part of the infrared ray IR2 can reach the adhesive layer 51 without colliding with the wiring layer 63. Then, the infrared ray IR2 reaching the adhesive layer 51 is reflected by the surfaces of the adhesive layer 51 and the substrate 50 and detected by the infrared camera 41. Note that, in FIG. 8, the infrared ray IR1 indicates a partial infrared ray emitted from the first infrared source 31. The same applies to the infrared ray IR2.

### Effects of Present Embodiment

(1) In the above embodiment, the infrared camera 41 moves in the same range as the first range A1 which is the mounting region of the electronic component 60. That is, the infrared camera 41 can photograph at least the inside of the first range A1. According to this configuration, mounting of the electronic component 60 on the substrate 50 and photographing by the infrared camera 41 can be performed without moving the substrate 50 on the stage 11. As a result, time and labor for transferring the substrate 50 can be omitted.
(2) In the above embodiment, the first infrared source 31 is located on the side farther from the main surface 11A with respect to the uppermost position P in a direction orthogonal to the main surface 11A. That is, the first infrared source 31 is located at a position that does not interfere with the mounting head 21. According to this configuration, it is possible to suppress complication of the control of the movement of the mounting head 21.
(3) In the above embodiment, the first infrared source 31 is located within the first range A1 in a direction parallel to the main surface 11A. Therefore, the first infrared source 31 easily irradiates the entire substrate 50 on the main surface 11A with infrared rays from immediately above the main surface 11A. The second infrared source 32 is located outside the first range A1. That is, the second infrared source 32 can irradiate the substrate 50 at an angle different from that of the first infrared source 31. As a result, the second infrared source 32 can irradiate a place to which the infrared ray of the first infrared source 31 does not reach with the infrared ray. In this manner, the first infrared source 31 and the second infrared source 32 can be handled as a non-directional, non-shadow light source as a whole. In addition, since the second infrared source 32 is located outside the first range A1, it does not interfere with the mounting head 21 in the mounting step S12.
(4) In the above embodiment, the second infrared source 32 is located within the second range A2 in a direction orthogonal to the main surface 11A. Therefore, the second infrared source 32 irradiates the substrate 50 with infrared rays at a position closer to the main surface 11A than the first infrared source 31. Therefore, the infrared rays from the second infrared source 32 reach the substrate 50 without being blocked by the first infrared source 31. Specifically, the second infrared source 32 can irradiate the adhesive layer 51 immediately below the electronic component 60 with infrared rays.
(5) In the above embodiment, the inspection step S13 is performed on the electronic component 60 mounted on the substrate 50 in parallel with the mounting step S12 performed by the mounting head 21 on the electronic component 60 not mounted on the substrate 50. According to this configuration, the time from the start of the mounting step S12 to the end of the inspection step S13 can be shortened.
(6) In the above embodiment, the base material 61 of the electronic component 60 is made of a material capable of transmitting infrared rays. This configuration is suitable for inspecting the adhesive layer 51 immediately below the electronic component 60.

### Modification Examples

The above-mentioned embodiments and the following modifications can be implemented in combination within a range that is not technically contradictory.

### Modification Example of Electronic Component Mounting Apparatus

The configuration of the stage 11 is not limited to the example of the above embodiment. For example, the stage 11 may have a circular shape. In addition, the stage 11 may not have a mechanism for fixing the substrate 50 as long as the substrate 50 can be placed on the main surface 11A.

The mounting head 21 only needs to be movable within a two-dimensional range parallel to at least the main surface 11A. The movable range of the mounting head 21 is not limited to the range on the substrate 50. That is, the first range A1 may include a region outside the substrate 50. The first range A1 may be a region smaller than the area of the substrate 50.

The mechanism for mounting the electronic component 60 on the substrate 50 by the mounting head 21 is not limited to the suction mechanism. For example, the mounting head 21 may have viscosity, and the electronic component 60 may be mountable on the substrate 50 using the viscosity. In addition, the mounting head 21 may include a clamp mechanism, and the electronic component 60 may be sandwiched and held by the mechanism.

The wavelength of the infrared ray detected by the infrared camera 41 in the above embodiment is merely an example. The wavelength detected by the infrared camera 41 can be appropriately changed in accordance with the transmission characteristics of each infrared source and the inspection target.

The infrared camera 41 only needs to be able to photograph at least the inside of the mounting region of the electronic component 60. That is, the infrared camera 41 only needs to be movable in a region including the first range A1 in a direction parallel to the main surface 11A. Furthermore, the infrared camera 41 may not be able to move as long as the entire mounting region of the electronic component 60 can be photographed with a necessary resolution.

In the above embodiment, the configuration of the first infrared source 31 is not limited to the example of the above embodiment. For example, the shape of the first infrared source 31 may be a circular shape, a ring shape, or the like. In addition, the first infrared source 31 may not be directed toward the main surface 11A as a whole. The first infrared source 31 may be located outside the first range A1.

The second infrared source 32 may be located within the first range A1 or may be located outside the second range A2.

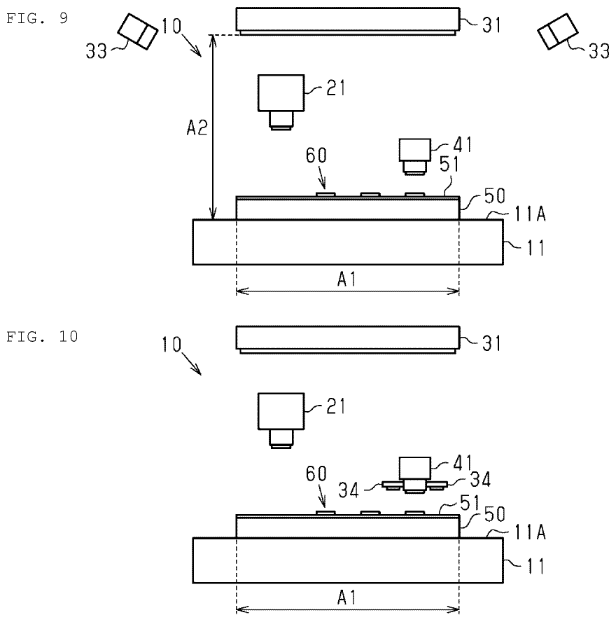

The configuration of the second infrared source is not limited to the example of the above embodiment. For example, in the example illustrated in FIG. 9, a second infrared source 33 has a ring shape. In FIG. 9, only a part of the second infrared source 33 is illustrated. The second infrared source 33 is located outside the mounting region of the electronic component 60 in a direction parallel to the main surface 11A. That is, the second infrared source 33 is located outside the first range A1. In addition, the second infrared source 33 is located at substantially the same position as the first infrared source 31 in a direction orthogonal to the main surface 11A. In the example illustrated in FIG. 9, the second infrared source 33 is directed in an oblique direction with respect to the main surface 11A as a whole. Further, the second infrared source 33 emits the infrared ray obliquely toward the main surface 11A side of the stage 11 on the ring-shaped center side of the second infrared source 33 as a whole. Therefore, in the case of this modification example, most of the infrared rays emitted from the second infrared source 33 are emitted to the substrate 50.

The second infrared source may be movable. For example, in the example illustrated in FIG. 10, a second infrared source 34 is fixed to the infrared camera 41. In this example, the second infrared source 34 has a ring shape. Then, the lens of the infrared camera 41 is located inside the ring-shaped second infrared source 34. In this example, the second infrared source 34 is movable with the infrared camera 41. In such a configuration, the infrared ray emitted from the second infrared source 34 is hardly blocked by the infrared camera 41. In addition, the second infrared source 34 can efficiently irradiate the imaging range of the infrared camera 41 with infrared rays.

In the above embodiment, the positional relationship between the first infrared source 31 and the second infrared source 32 is not limited. For example, both the first infrared source 31 and the second infrared source 32 may be located outside the first range A1, or may be located within the first range A1. In addition, one or more infrared sources may be provided, and the second infrared source 32 can be omitted.

### Modification Examples of Substrate and Electronic Component

The configuration of the substrate 50 is not limited to the example of the above embodiment. For example, the material of the substrate 50 may be, for example, a material containing glass, SiC, another synthetic resin, or the like as a main component. In addition, the shape and dimension of the substrate 50 may be different from those of the example of the above embodiment. For example, the substrate 50 may have a square plate shape having a side of 1000 mm or the like.

In the above embodiment, the material of the adhesive layer 51 is not limited to the example of the above embodiment. For example, the adhesive layer 51 may contain an insulating filler. Further, the adhesive layer 51 may be solder or the like. That is, the main component of the adhesive layer 51 is not limited to an organic substance.

The configuration of the electronic component 60 is not limited to the example of the above embodiment. For example, the barrier metal 62 can be omitted from the electronic component 60. As the electronic component 60, an insulating resin or the like can be adopted instead of the barrier metal 62. The material of the wiring layer 63 is also not limited. As a material of the base material 61, SiC, GaN, Ge, GaAs, InP, gallium oxide, or the like can be adopted as a material capable of transmitting infrared rays.

The surface of the substrate 50 may not be covered with the adhesive layer 51. In that case, in the electronic component 60, the surface facing the substrate 50 may be covered with the adhesive layer 51. That is, the electronic component 60 may be mounted on the substrate 50 via the adhesive layer 51.

### Modification Examples of Electronic Component Mounting Method

In the above embodiment, the substrate 50 having the adhesive layer 51 formed on the surface thereof is placed on the main surface 11A of the stage 11, but the adhesive layer 51 may be formed on the upper surface of the substrate 50 after the substrate 50 is placed on the main surface 11A of the stage 11. Even in this case, it can be said that the substrate 50 on which the adhesive layer 51 is formed is placed on the main surface 11A.

In the above embodiment, the retreating step S14 can be omitted. That is, the mounting head 21 may not be moved to the outside of the first range A1. For example, after the mounting step S12 is completed, the mounting head 21 may be moved to a location other than immediately above the mounted electronic component 60.

The inspection step S13 may be started after the mounting step S12 on all electronic components 60 is completed. Also in this case, since the mounting step S12 and the inspection step S13 can be performed without moving the substrate 50 on the stage 11, time and labor for transferring the substrate 50 can be omitted.

### Supplementary Note

Technical ideas that can be derived from the above embodiments and modifications will be described below.

[1] An electronic component mounting apparatus including a stage having a main surface on which a substrate can be placed, a mounting head for mounting an electronic component on the substrate, an infrared camera capable of detecting infrared rays, and a first infrared source capable of emitting at least infrared rays. The mounting head is movable within a two-dimensional range parallel to the main surface, and the infrared camera is capable of photographing an inside of a mounting region of the electronic component.

[2] The electronic component mounting apparatus according to [1], the mounting head is movable in a direction orthogonal to the main surface, and when a position of the mounting head when the mounting head is farthest from the stage in a direction orthogonal to the main surface is defined as an uppermost position, the first infrared source is located on a side farther from the main surface with respect to the uppermost position in a direction orthogonal to the main surface.

[3] The electronic component mounting apparatus according to [2], further including a second infrared source capable of emitting at least infrared rays, in which the first infrared source is located within a mounting region of the electronic component in a direction parallel to the main surface, and the second infrared source is located outside a mounting region of the electronic component in a direction parallel to the main surface.

[4] The electronic component mounting apparatus according to [3], in which the second infrared source is located within a range from a position closest to the main surface in the first infrared source to the main surface in a direction orthogonal to the main surface.

[5] An electronic component mounting method performed by a mounting apparatus, in which the mounting apparatus includes a stage having a main surface on which a substrate can be placed; a mounting head for mounting an electronic component on the substrate; an infrared camera capable of detecting infrared rays; and an infrared source capable of emitting at least infrared rays. The mounting head is movable within a two-dimensional range parallel to the main surface, and the infrared camera is capable of photographing an inside of a mounting region of the electronic component. The method comprises a substrate placing step of placing the substrate on the main surface of the stage; a mounting step of mounting the electronic component on the substrate via an adhesive layer while relatively moving the mounting head with respect to the substrate on the stage; and an inspection step of inspecting the substrate, the electronic component, and the adhesive layer by photographing the substrate, the electronic component, and the adhesive layer with the infrared camera while emitting infrared rays from the infrared source after start of the mounting step.

[6] The electronic component mounting method according to [5], in which the inspection step is performed on an electronic component mounted on the substrate in parallel with the mounting step being performed on an electronic component not mounted on the substrate by the mounting head.

[7] The electronic component mounting method according to [5] or [6], in which the electronic component includes a base material and a wiring layer located on a surface of the base material, and a material of the base material is a material capable of transmitting infrared rays.

What is claimed is:

1. An electronic component mounting apparatus comprising:
a stage having a main surface on which a substrate can be placed;
a mounting head configured to mount an electronic component on the substrate, and configured to move within a two-dimensional range parallel to the main surface;
an infrared camera configured to detect infrared rays and photograph an inside of a mounting region of the electronic component; and
a first infrared source configured to emit at least infrared rays.

2. The electronic component mounting apparatus according to claim 1,
the mounting head is configured to move in a direction orthogonal to the main surface, and
when a position of the mounting head when the mounting head is farthest from the stage in a direction orthogonal to the main surface is defined as an uppermost position,
the first infrared source is on a side farther from the main surface with respect to the uppermost position in a direction orthogonal to the main surface.

3. The electronic component mounting apparatus according to claim 1, further comprising:
a second infrared source configured to emit at least infrared rays, wherein
the first infrared source is within a mounting region of the electronic component in a direction parallel to the main surface, and
the second infrared source is outside a mounting region of the electronic component in a direction parallel to the main surface.

4. The electronic component mounting apparatus according to claim 3, wherein
the second infrared source is within a range from a position closest to the main surface in the first infrared source to the main surface in a direction orthogonal to the main surface.

5. The electronic component mounting apparatus according to claim 2, further comprising:
a second infrared source configured to emit at least infrared rays, wherein
the first infrared source is within a mounting region of the electronic component in a direction parallel to the main surface, and
the second infrared source is outside a mounting region of the electronic component in a direction parallel to the main surface.

6. The electronic component mounting apparatus according to claim 5, wherein
the second infrared source is within a range from a position closest to the main surface in the first infrared source to the main surface in a direction orthogonal to the main surface.

7. An electronic component mounting method performed by a mounting apparatus, in which
the mounting apparatus includes:
a stage having a main surface on which a substrate can be placed;
a mounting head configured to mount an electronic component on the substrate;
an infrared camera configured to detect infrared rays; and
an infrared source configured to emit at least infrared rays,
the mounting head is configured to move within a two-dimensional range parallel to the main surface,
the infrared camera is configured to photograph an inside of a mounting region of the electronic component, and
the method comprises:
placing the substrate on the main surface of the stage;
mounting the electronic component on the substrate via an adhesive layer while relatively moving the mounting head with respect to the substrate on the stage; and
inspecting the substrate, the electronic component, and the adhesive layer by photographing the substrate, the electronic component, and the adhesive layer with the infrared camera while emitting infrared rays from the infrared source after start of the mounting.

8. The electronic component mounting method according to claim 7, wherein
the inspection is performed on an electronic component mounted on the substrate in parallel with the mounting being performed on an electronic component not mounted on the substrate by the mounting head.

9. The electronic component mounting method according to claim 7, wherein
the electronic component includes a base material and a wiring layer on a surface of the base material, and
a material of the base material is a material is configured to transmit infrared rays.

10. The electronic component mounting method according to claim 8, wherein
the electronic component includes a base material and a wiring layer on a surface of the base material, and
a material of the base material is a material is configured to transmit infrared rays.
